(19) United States
(12) Patent Application Publication
(10) Pub. No.: US 2016/0028040 A1
(43) Pub. Date: Jan. 28, 2016

(54) ELECTRODE STRUCTURE AND OLED DISPLAY

(71) Applicant: EverDisplay Optronics (Shanghai) Limited, Shanghai City (CN)

(72) Inventors: Wei-meng LEE, Shanghai City (CN); Kuo-cheng YU, Shanghai City (CN); Chun-chung LU, Shanghai City (CN); Hung-shun CHEN, Shanghai City (CN)

(21) Appl. No.: 14/681,741

(22) Filed: Apr. 8, 2015

(30) Foreign Application Priority Data
Jul. 22, 2014 (CN) 201410350583.0

(51) Int. Cl. H01L 51/52; H01B 1/02

(52) U.S. Cl. CPC H01L 51/5215; H01B 1/02

(57) ABSTRACT

The embodiments of the present disclosure relate to an electrode structure and OLED display. The electrode structure includes a first electrode layer, a second electrode layer and a third electrode layer. The first electrode layer includes at least one layer from Ti layer, Ti alloy layer, Zr layer and Zr alloy layer. The second electrode layer is formed on the first electrode layer. The third electrode layer is formed on the second electrode layer and includes at least one layer from Ti layer, Ti alloy layer, Zr layer and Zr alloy layer. The present disclosure saves massive rare metal indium, which can help to reduce the manufacture cost of OLED display. Meanwhile, it is not prone to delamination, rupture, exfoliation and so on at the first and third electrode layers, and thusly reduced light scattering due to Ti, Ti alloy, Zr or Zr alloy with good corrosion resistance.

### CROSS REFERENCE TO RELATED APPLICATIONS

This application claims the priority to and the benefit of Chinese Patent Application No. 201410350583.0, filed Jul. 22, 2014 and entitled “electrode structure and OLED display” which is incorporated herein by reference in its entirety.

### TECHNICAL FIELD

The present disclosure relates to microelectronic technology field, and, in particular, to an electrode structure and OLED display.

### BACKGROUND

Anodic metal structure of Active Matrix Organic Light Emitting Diode (AMOLED), such as a transparent conductive film formed by Indium tin oxide (ITO), has transparency and conductivity, which is successfully applied in optoelectronic industry. Nowadays, ITO-Ag-ITO film is commonly used as the anodic metal structure of AMOLED. However, an extensive use of the ITO may result in some disadvantageous: raw material shortage and costs rise and so on.

As shown in FIG. 1, a conventional ITO-Ag-ITO film includes a first ITO layer 11, an Ag layer 12 formed on the first ITO layer 11, and a second ITO layer 13 formed on the Ag layer 12. The ITO-Ag-ITO film has excellent transparency and conductivity, in particular, the conductivity thereof is about ten times of the single-layer ITO whereas the transparency thereof slightly decreased when compared with single-layer ITO. However, the Ag film has poor stability, and during film coating above a temperature of 200° C., the surface of the Ag film is rough, which will bring about a lower conductivity and transparency of the ITO-Ag-ITO film. Moreover, the results of a weather-resistance test shows that, after a long effect under environment with humidity, the Ag atom will still migrate across the interfaces even under the protection of the outer ITO layer, and a coalescence of the Ag film accordingly take place. Meanwhile, the phenomena such as delamination, rupture, exfoliation and so on will be occur on the outermost ITO layer, which will result in such a light scattering that some fuzzy white points on the ITO-Ag-ITO film will be observed by naked eye or optical microscope.

The above information disclosed in this Background section is only for enhancement of understanding of the background of the disclosure and therefore it may contain information that does not form the prior art that is already known in this country to a person of ordinary skill in the art.

### SUMMARY

The embodiments of the present disclosure provide an electrode structure with low manufacturing cost. The outer layer thereof is not easily stripped.

The embodiments of the present disclosure provide an OLED display including the electrode structure according to the embodiments of the present disclosure.

In one aspect, the present disclosure provides an electrode structure comprising a first electrode layer comprising at least one layer selected from the group consisting of Ti layer, Ti alloy layer, Zr layer and Zr alloy layer; a second electrode layer formed on the first electrode layer; and a third electrode layer formed on the second electrode layer and comprising at least one layer selected from the group consisting of Ti layer, Ti alloy layer, Zr layer and Zr alloy layer.

In another aspect, the present disclosure provides an OLED display comprising a substrate; an upper electrode located on the substrate; an organic layer located on the upper electrode; and a lower electrode located on the organic layer. The upper electrode or lower electrode is used as an anode comprising a first electrode layer comprising at least one layer selected from the group consisting of Ti layer, Ti alloy layer, Zr layer and Zr alloy layer; a second electrode layer formed on the first electrode layer; and a third electrode layer formed on the second electrode layer and comprising at least one layer selected from the group consisting of Ti layer, Ti alloy layer, Zr layer and Zr alloy layer.

It is evident from the embodiments mentioned above that the present disclosure has the following advantages:

In the present disclosure, both the first and the third electrode layers include at least one layer selected from the group consisting of Ti layer, Ti alloy layer, Zr layer and Zr alloy layer. That is, in the present invention, Ti layer, Ti alloy layer, Zr layer or Zr alloy layer is used to replace the conventional ITO layer, such that massive rare metal indium may be saved, and the manufacturing cost of OLED display is accordingly reduced. Meanwhile, the first and the third electrode layers can avoid such phenomena as delamination, rupture, exfoliation and thus the light scattering at the surfaces thereof, since Ti, Ti alloy, Zr or Zr alloy has a good corrosion resistance.

The foregoing summary is not intended to summarize each potential embodiment or every aspect of the present disclosure.

### BRIEF DESCRIPTION OF THE DRAWINGS

The foregoing and other features and advantages of the disclosure will be apparent to those skilled in the art in view of the following detailed description, taken in conjunction with the accompanying drawings.

FIG. 1 is a schematic view showing a conventional electrode structure.

FIG. 2 is a schematic view showing an electrode structure according to the first embodiment of the present disclosure.

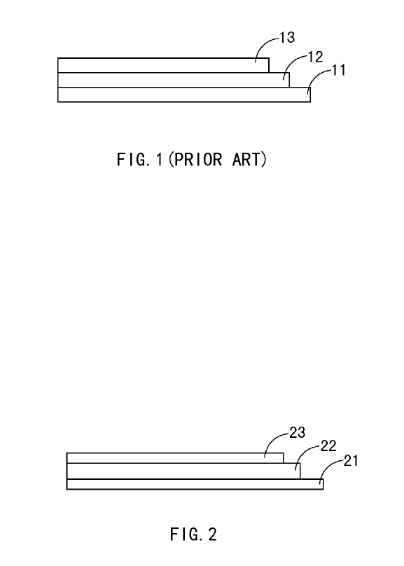

### DETAILED DESCRIPTION

Exemplary embodiments of the disclosure will now be described more fully with reference to the accompanying drawings, in which exemplary embodiments are shown. Exemplary embodiments of the disclosure may, however, be embodied in many different forms and should not be construed as being limited to the embodiments set forth herein; rather, these embodiments are provided so that this disclosure will be thorough and complete, and will fully convey the concept of exemplary embodiments to those skilled in the art. In the drawings, the thicknesses of layers and regions are exaggerated for clarity. Like reference numerals in the drawings denote like elements, and thus their description will be omitted.

The described features, structures, or/and characteristics of the disclosure may be combined in any suitable manner in one or more embodiments. In the following description, numerous specific details are disclosed to provide a thorough understanding of embodiments of the disclosure. One skilled in the relevant art will recognize, however, that the disclosure may be practiced without one or more of the specific details, or with other methods, components, materials, and so forth. In other instances, well-known structures, materials, or operations are not shown or described in detail to avoid obscuring aspects of the disclosure.

### The First Embodiment of the Electrode Structure

With reference to FIG. 2, the electrode structure according to the first embodiment of the present disclosure includes a first electrode layer 21, a second electrode layer 22, and a third electrode layer 23.

The first electrode layer 21 is Ti layer with a thickness of 60 nm.

The second electrode layer 22 is an Ag alloy layer, such as Ag—Ru alloy, Ag—Pd alloy, Ag—Ca alloy, Ag—V alloy or Ag—Nb alloy. The second electrode layer 22 has a thickness of 10 nm and may be formed on the first electrode layer 21 by evaporation, deposition or sputtering processes. The second electrode layer 22 may also be an Ag layer.

The second electrode layer 22 can also be formed by dispersing at least one compound phase in a matrix composed of Ag or Ag alloy, where the compound phase is formed by at least one selected from the group consisting of oxide, composite oxide, oxynitride, carbide, sulfide, chloride, silicide, fluoride, boride, hydride, phosphide, selenide and telluride of Al, Mg, Sn, Zn, In, Ti, Zr, Mn. The compound phase formed by the compound(s) of the eight metals mentioned above is dispersed in the matrix composed of Ag or Ag alloy, therefore, the Ag atom constituting the matrix is obstructed to migrate, such that the film planarity of the second electrode layer could be maintained. Hence, the reflectivity could be suppressed to be decreased, even the film is heated.

The third electrode layer 23 is Ti layer with a thickness of 60 nm and may be formed on the second electrode layer 22 by evaporation, deposition or sputtering processes.

In the above embodiment, the thickness of the first electrode layer 21 generally ranges from 10-100 nm, the thickness of the second electrode layer 22 ranges from 2-20 nm, the thickness of the third electrode layer 23 ranges from 10-100 nm. the thickness of first electrode layer 21 plus the thickness of the third electrode layer 23 is equal to or larger than 80% of the total thickness of the electrode structure.

In the above embodiment, the electrode structure is Ti—Ag alloy-Ti electrode structure. The Ag atom in the Ag alloy migrates relatively difficultly when compared with the Ag atom in the pure Ag. Moreover, the Ti has properties of light weight, high strength, good high and low-temperature resistance, strong acid and alkali resistance and so on, so as to provide an effective protection for the middle layer with Ag alloy. Consequently, the electrode structure according to the first embodiment is able to decrease significantly the deficiencies such as delamination, rupture, exfoliation and so on in the electrode structure. Meanwhile, the first, second and third electrode layer 21, 22 and 23 are manufactured without rare metal indium, such that the manufacturing cost is reduced.

### The Second Embodiment of the Electrode Structure

The electrode structure according to the second embodiment of the present disclosure includes a first electrode layer 21, a second electrode layer 22, and a third electrode layer 23, which has the following difference compared with the first embodiment:

Both the first electrode layer 21 and the second electrode layer 22 are Zr layer.

Zr has good corrosion resistance to many kinds of acid such as hydrochloride, nitric acid, sulfate acid, acetic acid or the like, and many kinds of alkali and salt. The first electrode layer 21 and the second electrode layer 22 made from Zr have property of good corrosion resistance which is the same with that of the first electrode layer 21 and the second electrode layer 22 made from Ti. Therefore, the electrode structure according to the second embodiment can also be able to significantly minimize such deficiencies as delamination, rupture, exfoliation and so on in the electrode structure, and to reduce the manufacturing cost thereof.

Other parts of the second embodiment are the same as that of the first embodiment and the detailed description is omitted herein.

In other embodiments, the first electrode layer 21 and the second electrode layer 22 may be Zr alloy layer. Zr alloy is a nonferrous alloy formed by adding other elements into a matrix of Zr. The Zr alloy mainly includes Zr-2 alloy (Zirca-loy-2), Zr-4 alloy (Zircaloy-4), Zr-1Nb alloy, Zr-2.5Nb alloy, V—Zr alloy layer, Zr—Ni alloy layer, Al—Zr alloy layer, Mg—Zr alloy layer or the like. Zr alloy has good corrosion resistance and temperate mechanical property in water and steam under high pressure and high temperature at 300˜400° C., which may be used as the first electrode layer 21 or the second electrode layer 22 and may decrease and even avoid deficiencies such as delamination, rupture, exfoliation and so on in the electrode structure.

In other embodiments, the first electrode layer 21 and the second electrode layer 22 may be Ti alloy. Ti alloy is a nonferrous alloy formed by adding other elements into a matrix of Ti. The Ti alloy includes Ti—Al—V alloy (Ti-6Al-4V). Ti—Al—Sn alloy (Ti-5Al-2.5Sn), Ti—Al—Zr alloy (Ti-2Al-2.5Zr), Ti—Mo alloy (Ti-32Mo), Ti—Mo—Ni alloy, Ti—Pd alloy or the like. Ti alloy has very high calorific intensity, which has an operation temperature several hundreds degree centigrade higher than that of Al alloy, thus having good corrosion resistance. Ti alloy has good corrosion resistance, which is far superior to stainless steel when working in medium of moist atmosphere and sea, has dramatic resistance to pitting corrosion, acid corrosion and stress corrosion, and has good corrosion resistance to alkali, chloride, chlorinated organic matter, nitric acid, sulfuric acid or the like. Ti alloy may be used as the first electrode layer 21 or the second electrode layer 22 and may decrease and even avoid deficiencies such as delamination, rupture, exfoliation and so on in the electrode structure.

The first electrode layer 21 and the second electrode layer 22 may be a single layer of Ti, Ti alloy, Zr or Zr alloy, or a composite layer composed of multiply layers with identical or different metal layers or alloy layers. The material of the first electrode layer 21 and the second electrode layer 22 may be the same or not.

The electrode structure according to the present disclosure is used as an anode of OLED.

In the electrode structure according to the present disclosure, the first electrode layer and the third electrode layer adopt at least one layer from Ti layer, Ti alloy layer, Zr layer and Zr alloy layer, which have benefit technical effects as follows.

(1) The electrode structure of the present disclosure used as an anode, which is made from high work-function material, such that the electrode structure of the present disclosure may better match the organic layer.

(2) Ti alloy may form TiO2 after annealing process, which is helpful to thermal stability. Moreover the resistance of Ti—Ag—Ti interface may be decreased due to the Ti with disorder arrangement, such that the electrode structure of the present disclosure has good thermal stability and low resistance.

(3) Tt is reduced the deficiencies such as delamination, rupture, exfoliation and so on of the outer layer, thus reduced light scattering.

(4) In the electrode structure according to the present disclosure, transparency may be improved by decreasing the width of the first electrode layer and the third electrode layer, or conductivity may be improved by increasing the width of the first electrode layer and the third electrode layer.

(5) It is possible to eliminate the limit of raw material shortage and costs rise by avoid using indium of the ITO which is rare metal.

### OLED Display

An OLED display provided by the present disclosure mainly includes a substrate, an upper electrode, an organic layer and a lower electrode.

For example, the substrate is a glass substrate, which may be transparent substrate, or flexible substrate.

The upper electrode is formed on the substrate by deposition, evaporation or sputtering processes.

The organic layer is formed on the upper electrode by deposition, evaporation or sputtering processes. The organic layer, for example, includes a hole injection layer, hole transport layer, electron injection layer, electron transport layer, and an emitter layer.

The lower electrode is formed on the organic layer by deposition, evaporation or sputtering processes.

As mentioned above, the upper electrode, for example, is anode, and then the lower electrode is cathode. Wherein, the upper electrode is the electrode structure according to the present disclosure, and the lower electrode may be a conventional electrode. Of course, it is feasible that the upper electrode is a conventional electrode, and the lower electrode is the electrode structure according to the present disclosure.

The OLED display of the present disclosure adopts the electrode structure according to the present disclosure as the anode, which may decrease and even avoid deficiencies such as delamination, rupture, exfoliation and so on at the outer layer in the electrode structure. Therefore, the present OLED display has a reduced light scattering and an improved image quality, and the manufacturing cost thereof is significantly reduced.

Exemplary embodiments have been specifically shown and described as above. It will be appreciated by those skilled in the art that the disclosure is not limited the disclosed embodiments; rather, all suitable modifications and equivalent which come within the spirit and scope of the appended claims are intended to fall within the scope of the disclosure.

What is claimed is:

1. An electrode structure comprising:
a first electrode layer comprising at least one layer selected from the group consisting of Ti layer, Ti alloy layer, Zr layer and Zr alloy layer;
a second electrode layer formed on the first electrode layer; and
a third electrode layer formed on the second electrode layer and comprising at least one layer selected from the group consisting of Ti layer, Ti alloy layer, Zr layer and Zr alloy layer.

2. The electrode structure according to claim 1, wherein the first and the third electrode layers are composed of the same material.

3. The electrode structure according to claim 2, wherein both the first electrode layer and the third electrode layer are Ti layer or Zr layer.

4. The electrode structure according to claim 3, wherein the second electrode layer is Ag layer or Ag alloy layer.

5. The electrode structure according to claim 1, wherein the thickness of the first electrode layer plus the thickness of the third electrode layer is not less than 80% of the total thickness of the electrode structure.

6. The electrode structure according to claim 2, wherein the thickness of the first electrode layer plus the thickness of the third electrode layer is not less than 80% of the total thickness of the electrode structure.

7. The electrode structure according to claim 3, wherein the thickness of the first electrode layer plus the thickness of the third electrode layer is not less than 80% of the total thickness of the electrode structure.

8. The electrode structure according to claim 7, wherein the thickness of the first electrode layer ranges from 10-100 nm, the thickness of the second electrode layer ranges from 2-20 nm, and the thickness of the third electrode layer ranges from 10-100 nm.

9. The electrode structure according to claim 1, wherein the Zr alloy layer is at least one layer selected from the group consisting of V—Zr alloy layer, Zr—Ni alloy layer, Al—Zr alloy layer, Mg—Zr alloy layer and Si—Zr alloy layer.

10. The electrode structure according to claim 1, wherein the Ti alloy layer is at least one layer selected from the group consisting of Ti—Al—V alloy, Ti—Al—Sn alloy, Ti—Al—Zr alloy, Ti—Mo alloy, Ti—Mo—Ni alloy and Ti—Pd alloy.

11. The electrode structure according to claim 1, wherein the electrode structure is used as anode of OLED.

12. An OLED display comprising:
a substrate,
an upper electrode located on the substrate;
an organic layer located on the upper electrode; and
a lower electrode located on the organic layer;
the upper electrode or lower electrode is used as an anode, and the anode comprising:
a first electrode layer comprising at least one layer selected from the group consisting of Ti layer, Ti alloy layer, Zr layer and Zr alloy layer;
a second electrode layer formed on the first electrode layer; and
a third electrode layer formed on the second electrode layer and comprising at least one layer selected from the group consisting of Ti layer, Ti alloy layer, Zr layer and Zr alloy layer.

13. The OLED display according to claim 12, wherein the first and the third electrode layers are composed of the same material.

14. The OLED display according to claim 13, wherein both the first electrode layer and the third electrode layer are Ti layer or Zr layer.

15. The OLED display according to claim 14, wherein the second electrode layer is Ag layer or Ag alloy layer.

16. The OLED display according to claim 12, wherein the thickness of the first electrode layer plus the thickness of the third electrode layer is not less than 80% of the total thickness of the electrode structure.

17. The OLED display according to claim 13, wherein the thickness of the first electrode layer plus the thickness of the third electrode layer is not less than 80% of the total thickness of the electrode structure.

18. The OLED display according to claim 17, wherein the thickness of the first electrode layer ranges from 10-100 nm, the thickness of the second electrode layer ranges from 2-20 nm, and the thickness of the third electrode layer ranges from 10-100 nm.

19. The OLED display according to claim 1, wherein the Zr alloy layer is at least one layer selected from the group consisting of V—Zr alloy layer, Zr—Ni alloy layer, Al—Zr alloy layer, Mg—Zr alloy layer and Si—Zr alloy layer.

20. The OLED display according to claim 1, wherein the Ti alloy layer is at least one layer selected from the group consisting of Ti—Al—V alloy, Ti—Al—Sn alloy, Ti—Al—Zr alloy, Ti—Mo alloy, Ti—Mo—Ni alloy and Ti—Pd alloy.
